(19) United States
(12) Patent Application Publication
(10) Pub. No.: US 2026/0063729 A1
(43) Pub. Date: Mar. 5, 2026

(54) Detection Device for an Electrical Energy Store of a Motor Vehicle With Dynamic Plausibility Checking

(71) Applicant: Bayerische Motoren Werke Aktiengesellschaft, Muenchen (DE)

(72) Inventors: Stefan BIELESCH, Muenchen (DE); Andreas MAERKL, Muenchen (DE); Kevin PLUCH, Muenchen (DE); Julian WIESMEIER, Muenchen (DE)

(21) Appl. No.: 18/997,679

(22) PCT Filed: Sep. 27, 2023
(86) PCT No.: PCT/EP2023/076731

§ 371 Date: Jan. 22, 2025

(30) Foreign Application Priority Data
Oct. 25, 2022 (DE) 10 2022 128 181.7

(51) Int. Cl. G01R 31/396; B60L 3/00; B60L 50/60; G01R 31/3842; G01R 31/52; H01M 10/48

(52) U.S. Cl. CPC G01R 31/396; B60L 3/0046; B60L 50/60; G01R 31/3842; G01R 31/52; H01M 10/482; H01M 2220/20

(57) ABSTRACT

A detection device for an electrical energy store of a motor vehicle for detecting a fault of at least one energy store cell of a circuit of energy storage cells of the energy store includes a current sensor for detecting current values of the circuit, a voltage sensor for detecting cell voltage values of the energy store cells, and a storage and evaluation apparatus to receive and temporarily store the current and cell voltage values over a predefined time span, to compare a dynamic of cell voltage profiles obtained from the temporarily stored cell voltage values of a time span with a dynamic of the current profile obtained from the temporarily stored current values of the time span, and to detect, on the basis of the comparison, a fault of at least one energy store cell.

### BACKGROUND AND SUMMARY

The invention relates to a detection device for an electrical energy store of a motor vehicle for detecting a fault of at least one energy storage cell of an interconnection of energy storage cells of the energy store. The detection device has a current sensor apparatus for detecting current values of the interconnection and a voltage sensor apparatus for detecting cell voltage values of the energy storage cells. The invention additionally relates to a method for detecting a fault of an energy storage cell, an electrical energy store and a motor vehicle.

In the present case, interest is focused on electrical energy stores which can be used as traction batteries for electrified motor vehicles for example. Electrical energy stores of this type usually have at least one interconnection of energy storage cells, which is arranged in an interior of a store housing of the electrical energy store. In the event of a fault of an energy storage cell, for example a cell-internal short circuit, a degasification of the energy storage cell may occur, by which heat and particles are transported into the interior of the store housing. As a result, further store components, for example further energy storage cells, may be damaged. Therefore, it is desirable to be able to detect such faults or cell defects.

For this, the energy store is usually equipped with a detection device for monitoring the energy storage cells, which has sensor apparatuses for detecting characteristics of the electrical energy store. Such sensor apparatuses are, for example, current sensor apparatuses for detecting current values of the energy storage cells and cell voltage sensors for detecting cell voltage values of the energy storage cells. For example, by comparing the detected cell voltage values with a predetermined voltage set-point value, a defective energy storage cell can be detected. Particularly in a parallel interconnection of energy storage cells, the voltage response of a defective energy storage cell is compensated in the unloaded state by the other energy storage cells however. Thus, a fault cannot or cannot always be detected on the basis of the comparison. In addition, it may come to pass that the voltage response of the energy storage cells changes in an ageing-related manner, so that the voltage set-point value has to be adjusted over time to prevent an incorrect diagnosis.

Therefore, further sensor apparatuses are therefore provided, for example temperature sensor apparatuses for detecting a temperature in the interior of the store housing and/or the energy storage cells, pressure sensor apparatuses for detecting a pressure in the interior of the store housing, light sensor apparatuses for detecting flames in the interior of the store housing, etc., which sensor apparatuses are primarily used for observing fault features which indicate an obvious defect of an energy storage cell. Such additional sensor apparatuses increase the costs and the weight of the electrical energy store however.

It is an object of the present invention to provide a simple and cost-effective solution for detecting a fault of an energy storage cell of an electrical energy store for a motor vehicle.

This object is achieved according to the invention by a detection device, a method, an electrical energy store and a motor vehicle with the features according to the present disclosure. Advantageous embodiments of the invention are also the subject matter of the description and the figures.

A detection device according to the invention for an electrical energy store of a motor vehicle is used for detecting a fault of at least one energy storage cell of an interconnection of energy storage cells of the energy store. The detection device has a current sensor apparatus for detecting current values of the interconnection and a voltage sensor apparatus for detecting cell voltage values of the energy storage cells. Furthermore, the detection device has a storage and evaluation apparatus that is designed to receive the current values and the cell voltage values and temporarily store same over a predetermined time period, to compare a respective dynamic of cell voltage curves obtained from the temporarily stored cell voltage values of a time period with a dynamic of the current curve obtained from the temporarily stored current values of the time period and to detect a fault of at least one energy storage cell on the basis of the comparison.

The invention additionally includes a method for detecting a fault of at least one energy storage cell of an interconnection of energy storage cells of an electrical energy store. In the method, current values of the interconnection and cell voltage values of the energy storage cells are detected. These current values and cell voltage values are received and temporarily stored over a predetermined time period. Then, a respective dynamic of cell voltage curves obtained from the temporarily stored cell voltage values of a time period is compared with a dynamic of the current curve obtained from the temporarily stored current values of the time period and a fault of the at least one energy storage cell is detected on the basis of the comparison.

An electrical energy store according to the invention comprises an interconnection of electrical energy storage cells and a detection device according to the invention. The electrical energy store is a high-voltage energy store in particular and is used as a rechargeable traction battery for an electrified motor vehicle. The electrical energy store has a multiplicity of energy storage cells or battery cells, for example prismatic cells, round cells or pouch cells, which are interconnected with one another and are arranged in an interior of a store housing of the electrical energy store. Preferably, the interconnection of energy storage cells has at least one parallel circuit or a parallel composite made of at least two energy storage cells.

To monitor the energy storage cells, the electrical energy store has the detection device. The detection device is designed to detect a fault of at least one energy storage cell, that is to say a cell defect, on the basis of the measured current values of the energy storage cells and the measured cell voltage values of the energy storage cells. In particular, the detection device is designed to detect the fault only on the basis of the measured current values and the measured cell voltage values, without the use of sensor data of other sensor apparatuses and without a comparison of the measured values with predetermined set-point values. To this end, the detection device has the voltage sensor apparatus, which in particular has a voltage sensor for measuring cell-specific cell voltage values for each energy storage cell, and the current sensor apparatus, which in particular has at least one current sensor for measuring a current flowing through the interconnection for each interconnection. The current flowing through the interconnection in this case corresponds to a corresponding current through the individual energy storage cells.

The current values and cell voltage values detected by the current sensor apparatus and the voltage sensor apparatuses are transmitted to the storage and evaluation apparatus of the detection device and temporarily stored or buffered there for a predetermined time period, for example for at most a few seconds. The storage and evaluation apparatus can for example be integrated into an energy-store-internal control device and be connected in terms of communication technology, for example in a wired manner, to the current sensor apparatus and the voltage sensor apparatus. The storage and evaluation apparatus in particular has a buffer or intermediate store for temporary storage of the current values and cell voltage values, which is designed to store the current values and cell voltage values continuously in an ongoing manner over the predetermined time period. Therefore, current and cell voltage values are continuously stored temporarily in the buffer over the predetermined time period, wherein for each newly arriving up-to-date value, the oldest value can be deleted again. The buffer therefore has a fixed window size in particular, wherein the window size corresponds to the time period. The buffer therefore has the up-to-date current and cell voltage values and a predetermined number of past current and cell voltage values that were detected in the past.

On the basis of the current values and cell voltage values stored temporarily over the time period, a current curve or current signal and cell voltage curves or cell voltage signals can be determined. The cell voltage curves are then compared with the current curve. The invention is based on the discovery that the dynamic of the cell voltage curves should follow the dynamic of the current curve in the case of fault-free energy storage cells. If the dynamic of a cell voltage curve deviates from the dynamic of the current curve, then this indicates a defect of the associated energy storage cell. For cell monitoring, the plausibility of the dynamic of the cell voltage curves is checked on the basis of the dynamic of the current curve.

For example, the storage and evaluation apparatus is designed, for determining and comparing the dynamics, to determine gradients of the cell voltage curves and of the current curve and to detect the fault of at least one energy storage cell in the event that the gradient of the associated cell voltage curve is directed oppositely to the gradient of the current curve at least in sections. In a fault-free case, a positive gradient of the cell voltage signal, which results from increasing cell voltage values, should therefore follow a positive gradient of the current signal, which results from increasing current values. Conversely, in a fault-free case, a negative gradient of the cell voltage signal, which results from decreasing cell voltage values, should follow a negative gradient of the current signal, which results from decreasing current values. If the gradient of a cell voltage signal deviates in terms of sign from the gradient of the current signal, at least in sections, then the fault of the associated energy storage cell is detected.

The method carried out by the detection device, in which only the plausibility of the dynamics of the current curve and the cell voltage curves with respect to one another are checked for fault detection, is particularly advantageous as it is independent of ageing-related changes of the voltage response of the energy storage cells. Therefore, no set-point values have to be provided and calibrated in an ongoing manner. In addition, defects are also detected by the method, which could not be detected on the basis of nothing more than the voltage response owing to the defect-compensating parallel composite of the energy storage cells.

The invention additionally includes a motor vehicle with an electrical energy store according to the invention. The motor vehicle is a motor vehicle that can be driven electrically in the form of an electric or hybrid vehicle and has the electrical energy store as traction battery.

The embodiments presented with reference to the detection device and their advantages apply accordingly for the method according to the invention, for the electrical energy store according to the invention and for the motor vehicle according to the invention.

Further features of the invention emerge from the claims, the figures and the description of the figures. The features and feature combinations mentioned previously in the description and also the features and feature combinations mentioned in the following in the description of the figures and/or shown solely in the figures can be used not only in the respectively specified combination, but also in other combinations or in isolation.

The invention is now explained in more detail on the basis of a preferred exemplary embodiment and with reference to the drawings.

### BRIEF DESCRIPTION OF THE DRAWINGS

FIG. 1 shows a schematic illustration of an electrical energy store of a motor vehicle;

FIGS. 2a, 2b, and 2c show current and cell voltage curves of fault-free energy storage cells of the electrical energy store; and

FIG. 3 shows current and cell voltage curves of a fault-free and a defective energy storage cell.

### DETAILED DESCRIPTION OF THE DRAWINGS

In the figures, the same and functionally identical elements are provided with the same reference signs.

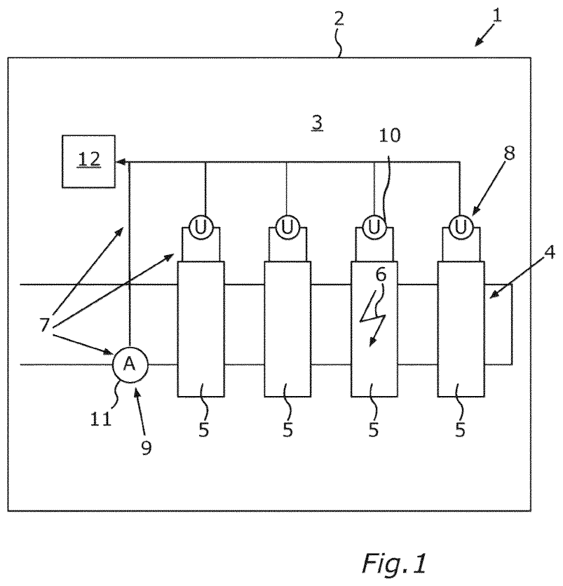

FIG. 1 shows an electrical energy store 1 for a motor vehicle. The electrical energy store 1 has a store housing 2, in the interior 3 of which at least one interconnection 4 of energy storage cells 5 is arranged. To detect a fault 6 or cell defect of an energy storage cell 5 of the interconnection 4, for example an impending cell degasification owing to a cell-internal short circuit, the electrical energy store I additionally has a detection device 7 which has a voltage sensor apparatus 8 and a current sensor apparatus 9. The voltage sensor apparatus 8 here has a voltage sensor 10 for measuring cell voltage values of the respective energy storage cell 5 for each energy storage cell 5. The current sensor apparatus 9 here has a current sensor 11 for measuring current values of the interconnection 4 for each interconnection 4. The detection device 7 additionally has a storage and evaluation apparatus 12 which is coupled with the voltage sensor apparatus 8 and the current sensor apparatus 9 and to which the detected cell voltage values and current values are transmitted. The transmitted cell voltage values and current values are temporarily stored by the storage and evaluation apparatus 12 over a predetermined time period Δt1, Δt2, Δt3.

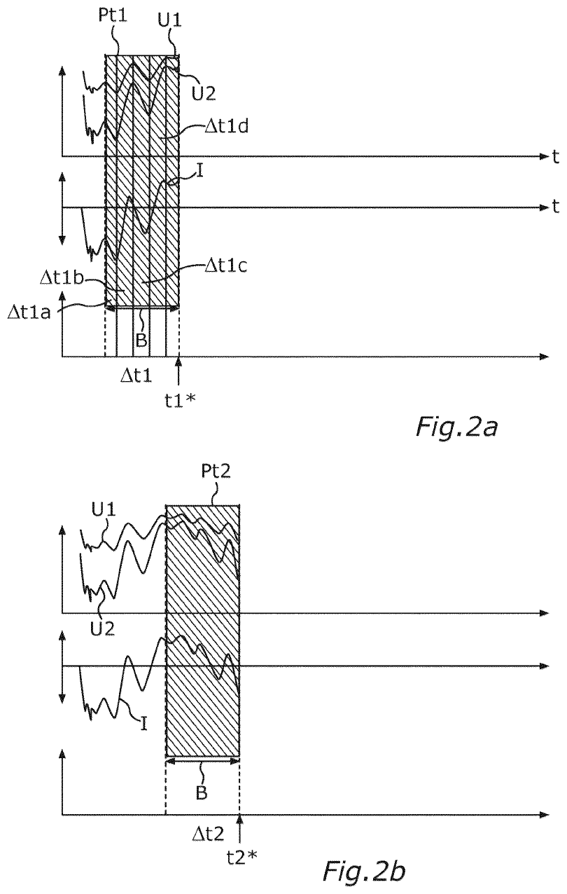

FIG. 2a, FIG. 2b and FIG. 2c show a current curve I of the interconnection 4, which progresses with the latest time point t1*, t2*, t3*, and two cell voltage curves U1, U2 of two fault-free energy storage cells 5 over time t, which progress with the latest time point t1*, t2*, t3*. In addition, a buffer window Pt1, Pt2, Pt3 of size B is shown, which progresses with the latest time point t1*, t2*, t3*, wherein the size B of the buffer window Pt1, Pt2, Pt3 corresponds to the respective time period Δt1, Δt2, Δt3 within which the values measured by the sensor apparatuses 8, 9 are temporarily stored and analyzed in the storage and evaluation unit 12. For fault detection, the latest buffer window Pt1, Pt2, Pt3 is considered, which buffer window comprises the current and cell voltage values of the latest time point t1*, t2*, t3* and the current and cell voltage values which were taken in the latest time period Δt1, Δt2, Δt3. In other words, a “past” of the current values and cell voltage values, which past covers a predetermined time period, is continuously evaluated.

For each buffer window Pt1, Pt2, Pt3, the dynamics of the cell voltage curves U1, U2 are compared with the dynamic of the current curve I. In addition, the dynamics of the cell voltage curves U1, U2 can also be compared with one another and thus the plausibility thereof can be checked with respect to one another. In FIG. 2a to FIG. 2c, the dynamics of the cell voltage curves U1, U2 are equal to the dynamic of the current curve I in each buffer window Pt1, Pt2, Pt3. For dynamic plausibility checking, it is possible to consider a sequence of the gradients of the cell voltage curves U1, U2 and the current curve I within the respective time period Δt1, Δt2, Δt3. For example, the gradients of the curves U1, U2, I in section Δt1a of the first time period Δt1 have a negative sign in each case and in the subsequent section Δt1b of the first time period Δt1 have a positive sign in each case. The gradients of the curves U1, U2, I have a negative sign in section Δt1c and have a positive sign again in the subsequent section Δt1d. Also, in the buffer window Pt2, the sequence of sections with negative and positive gradients is the same in the case of the cell voltage signals U1, U2 and the current signal I. In the third time window B3, all curves U1, U2, I have a gradient of 0, so here also the gradients of all curves U1, U2, I have the same sign. Therefore, as soon as the gradients of the cell voltage curves U1, U2 and the gradient of the current curve I have the same direction in mutually corresponding sections of the time periods Δt1, Δt2, Δt3, the dynamics are the same and the energy storage cells 5 are classified as fault-free.

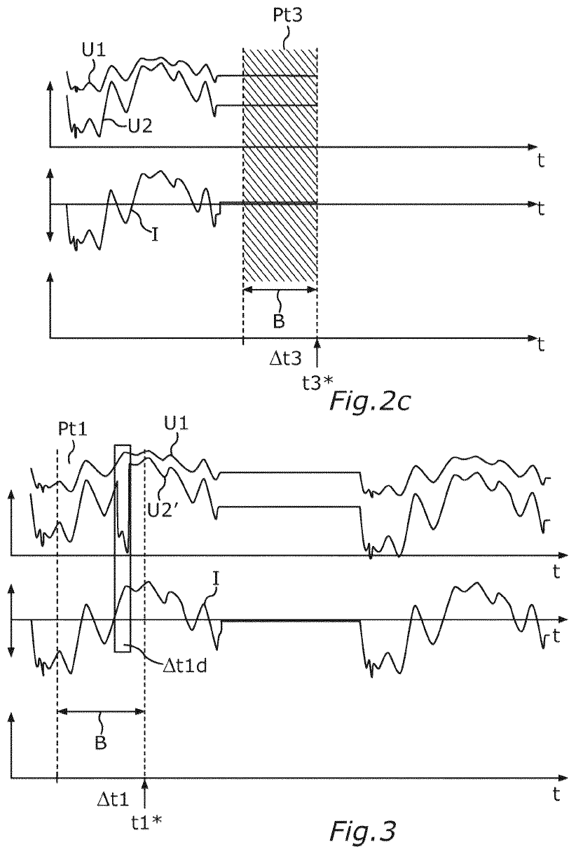

FIG. 3 shows the cell voltage curve U2′ for a defective energy storage cell 5. Here, the dynamic of the cell voltage curve U2′ deviates in buffer window Pt1 from the dynamic of the current signal I. This can be seen in the section Δt1d in which the gradient of the current signal I is positive, while the gradient of the cell voltage signal U2′ is at least partially negative. The gradient of the cell voltage signal U2′ is therefore oppositely directed to the gradient of the current signal I. This deviation of the dynamic of the cell voltage curve U2′ from the dynamic of the current curve I is detected by the storage and evaluation apparatus 12 and the energy storage cell 5 belonging to the cell voltage curve U2′ is classified as faulty or defective.

1-9. (canceled)

10. A detection device for an electrical energy store of a motor vehicle for detecting a fault of at least one energy storage cell of an interconnection of energy storage cells of the energy store, the detection device comprising:
a current sensor configured to detect current values of the interconnection;
a voltage sensor configured to detect cell voltage values of the energy storage cells; and
a storage and evaluation apparatus configured to:
receive the current values and the cell voltage values;
temporarily store the current values and the cell voltage values over a predetermined time period;
compare a respective dynamic of cell voltage curves obtained from the temporarily stored cell voltage values of a time period with a dynamic of the current curve obtained from the temporarily stored current values of the time period; and
detect a fault of at least one energy storage cell on a basis of the comparison.

11. The detection device according to claim 10,
wherein the voltage sensor comprises a voltage sensor for each energy storage cell.

12. The detection device according to claim 10,
wherein the current sensor comprises a current sensor for each interconnection.

13. The detection device according to claim 10,
wherein the storage and evaluation apparatus is configured to:
determine gradients of the cell voltage curves and the current curve; and
detect the fault of at least one energy storage cell in response to a gradient of the associated cell voltage curve being directed oppositely to a gradient of the current curve at least in sections.

14. The detection device according to claim 10,
wherein the storage and evaluation apparatus comprises a buffer configured to store the current values and the cell voltage values temporarily and continuously in an ongoing manner over the predetermined time period.

15. An electrical energy store for a motor vehicle, comprising:
at least one interconnection of electrical energy storage cells; and
the detection device according to claim 10.

16. The electrical energy store according to claim 15,
wherein the interconnection of the energy storage cells has at least one parallel circuit made of at least two energy storage cells.

17. A motor vehicle comprising:
the electrical energy store according to claim 15.

18. A method for detecting a fault of at least one energy storage cell of an interconnection of energy storage cells of an electrical energy store, the method comprising:
detecting current values of the interconnection;
detecting cell voltage values of the energy storage cells;
receiving and temporarily storing the current values and the cell voltage values over a predetermined time period;
comparing a respective dynamic of cell voltage curves obtained from the temporarily stored cell voltage values of a time period with a dynamic of the current curve obtained from the temporarily stored current values of the time period; and
detecting a fault of at least one energy storage cell on a basis of the comparison.

19. The method according to claim 18, comprising:
detecting the cell voltage values using a voltage sensor for each energy storage cell.

20. The method according to claim 18, comprising:
detecting the current values using a current sensor for each interconnection.

21. The method according to claim 18, comprising:
determining gradients of the cell voltage curves and the current curve; and
detecting the fault of at least one energy storage cell in response to a gradient of the associated cell voltage curve being directed oppositely to a gradient of the current curve at least in sections.

22. The method according to claim 18, comprising:
storing the current values and the cell voltage values in a buffer temporarily and continuously in an ongoing manner over the predetermined time period.
